(19) United States
(12) Patent Application Publication
(10) Pub. No.: US 2012/0250254 A1
(43) Pub. Date: Oct. 4, 2012

(54) MOTOR CONTROL APPARATUS

(75) Inventors: Makoto KOJYO, Fukuoka (JP); Toshiaki FUJIKI, Fukuoka (JP); Kazutaka KISHIMOTO, Fukuoka (JP)

(73) Assignee: KABUSHIKI KAISHA YASKAWA DENKI, Kitakyushu-shi (JP)

(21) Appl. No.: 13/365,259

(22) Filed: Feb. 3, 2012

(30) Foreign Application Priority Data
Mar. 28, 2011 (JP) 2011-069300

(51) Int. Cl. H05K 7/20

(52) U.S. Cl. 361/692

(57) ABSTRACT

A motor control apparatus is configured to control driving of a motor. The motor control apparatus includes a housing base, a main portion, an air duct, a heat dissipating component, and a heat sink. The housing base has one surface and another surface. The main portion is on the one surface of the housing base and includes a substrate. Through the air duct, cooling air passes. The air duct is on the other surface of the housing base. The heat dissipating component is on the one surface of the housing base and is coupled to the substrate. The heat sink includes a base portion and at least one fin. The heat sink is on the other surface of the housing base at a position corresponding to the heat dissipating component with the housing base disposed between the base portion and the heat dissipating component.

### CROSS-REFERENCE TO RELATED APPLICATIONS

The present application claims priority under 35 U.S.C. §119 to Japanese Patent Application No. 2011-069300, filed Mar. 28, 2011. The contents of this application are incorporated herein by reference in their entirety.

### BACKGROUND OF THE INVENTION

1. Field of the Invention

The present invention relates to a motor control apparatus configured to control driving of a motor.

2. Discussion of the Background

As disclosed in Japanese Unexamined Patent Application Publication No. 2002-280779, a conventional cooler for an electronic device includes a heat sink and a plurality of electronic components disposed on the heat sink. The heat sink with the plurality of electronic components is to be forcibly cooled. The heat sink includes a base portion (heat sink substrate) and heat discharge fins on one surface of the base portion. The plurality of electronic components include heat dissipating components (electronic components generating large amounts of heat) and are secured to the base portion. A housing (air channel cover) is mounted to the heat sink.

In mounting of the housing to the heat sink, in other words, in mounting of the heat sink to the top surface of the housing, the fins of the heat sink are passed through an opening on the top surface of the housing, and the base portion of the heat sink is secured to one side of the top surface of the housing. Thus, the fins of the heat sink are accommodated in the housing, and the heat of the heat dissipating components, which are in close contact with the base portion, is discharged through the base portion and the fins.

### SUMMARY OF THE INVENTION

According to one aspect of the present invention, a motor control apparatus is configured to control driving of a motor. The motor control apparatus includes a housing base, a main portion, an air duct, a heat dissipating component, and a heat sink. The housing base has one surface and another surface. The main portion is on the one surface of the housing base and includes a substrate. Through the air duct, cooling air passes. The air duct is on the other surface of the housing base. The heat dissipating component is on the one surface of the housing base and is coupled to the substrate. The heat sink includes a base portion and at least one fin. The heat sink is on the other surface of the housing base at a position corresponding to the heat dissipating component with the housing base disposed between the base portion and the heat dissipating component.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a perspective view, on the housing side, of an inverter device according to an embodiment;

FIG. 2 is a perspective view, on the air duct side, of the inverter device, illustrating a situation prior to mounting of the heat sink to the housing base;

FIG. 3 is a perspective view, on the air duct side, of the inverter device, illustrating a situation after mounting of the heat sink to the housing base;

FIG. 4 is a cross-sectional view of the inverter device;

FIG. 5 is a cross-sectional view of an inverter device according to a comparative example; and

FIG. 6 is a cross-sectional view of an inverter device according to a modification, illustrating integral die casting of the housing base, the air duct walls, and the bosses.

### DESCRIPTION OF THE EMBODIMENTS

The embodiments will now be described with reference to the accompanying drawings, wherein like reference numerals designate corresponding or identical elements throughout the various drawings.

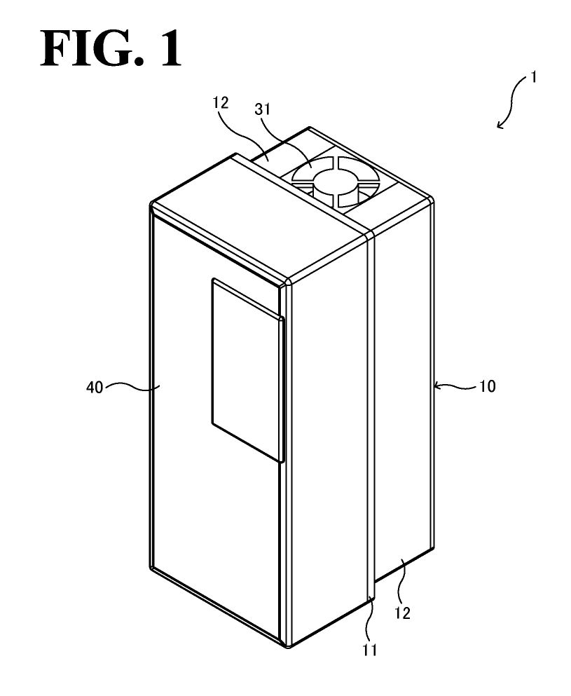

As shown in FIGS. 1 to 4, an inverter device 1 (motor control apparatus) according to this embodiment is an apparatus to control driving of a motor (not shown). The inverter device 1 includes a housing 10, a main portion 20, an air duct 30, a cover 40, a plurality of bosses 50, and a heat sink 60. Cooling air passes through the air duct 30. The cover 40 accommodates the main portion 20. The bosses 50 each have an approximately cylindrical shape. The heat sink 60 has an approximately rectangular parallelepiped shape.

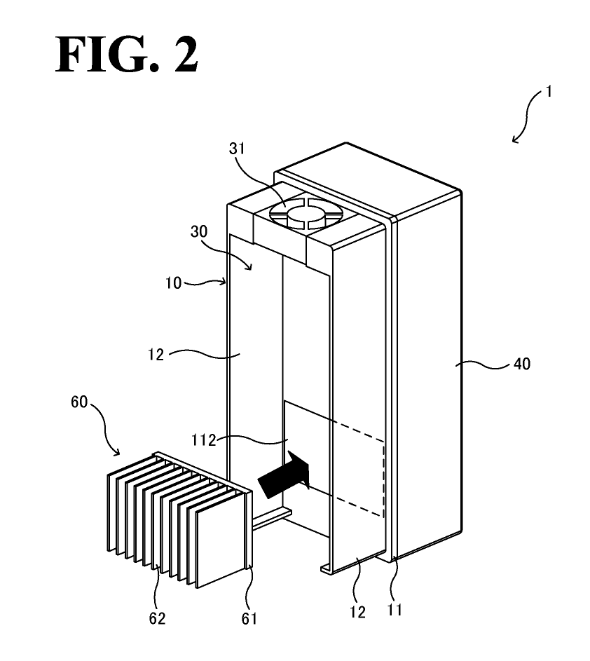

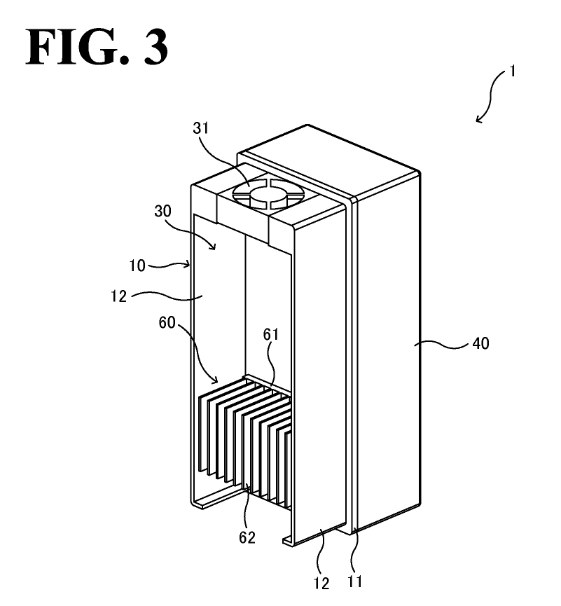

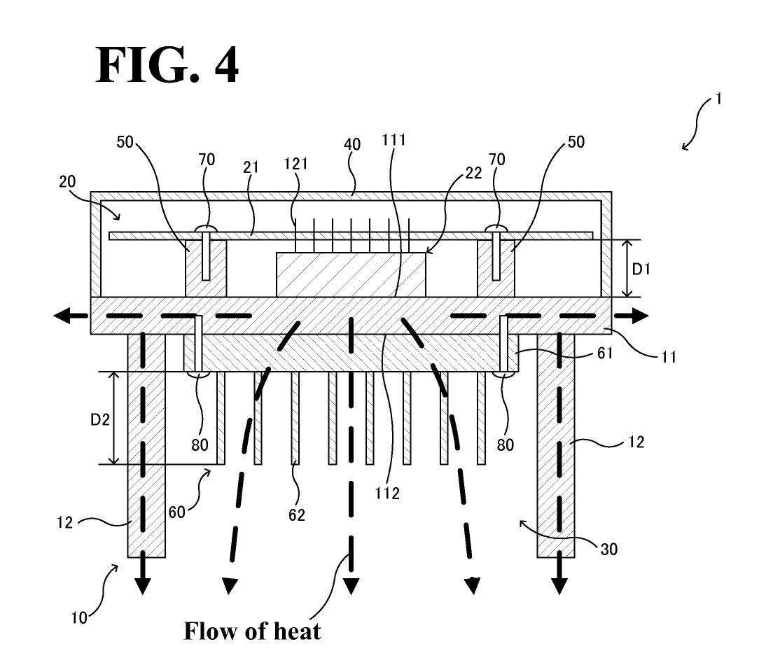

The housing 10 includes a housing base 11 and two air duct walls 12. The two air duct walls 12 are upright behind the housing base 11 (in other words, on the other surface of housing base 11, as seen on the rear-right side in FIG. 1, the front-left side in FIGS. 2 and 3, and the lower side in FIG. 4). The two air duct walls 12 constitute side walls of the air duct 30. The housing base 11 and the air duct walls 12 are individually die-cast from aluminum alloys (examples including, but not limited to, ADC12, which is an Al—Si—Cu alloy), and joined to one another with, for example, bolts. As used herein, the term die casting refers to a mold casting method by which molten metal is pressed into a mold to make molded articles in large quantities with high dimensional accuracy in short time. The term die casting also refers to products resulting from the mold casting method. The housing base 11 and the air duct walls 12 may be integrally die-cast from an aluminum alloy. Other examples of the die casting alloy than aluminum alloys include, but not limited to, zinc alloys and magnesium alloys.

The main portion 20 is disposed in front of the housing base 11 (in other words, one surface of the housing base 11, as seen on the front-left side in FIG. 1, the rear-right side in FIGS. 2 and 3, the upper side in FIG. 4). The main portion 20 includes: a substrate 21, on which an electronic circuit (not shown) is disposed; and a plurality of electronic components associated with the driving of the motor, including a power module 22 (heat dissipating component). The power module 22 incorporates a semiconductor device, not shown, such as an IGBT (Insulated Gate Bipolar Transistor), and also includes a plurality of external electrode terminals 121 coupled to the substrate 21. On the front surface of the housing base 11 (that is, on the one surface thereof), a region 111 (which is a region where the heat dissipating component is disposed) is disposed having a surface planed by a known appropriate process. The power module 22 is in close contact with the region 111.

Also on the front surface of the housing base 11, the plurality of bosses 50 are disposed in upright orientation to support the substrate 21. The bosses 50 are independent entities relative to the housing base 11 and are mounted to the front surface of the housing base 11 with, for example, studs. The distance between the housing base 11 and the substrate 21, that is, the length of each boss 50, is assumed D1. The substrate 21 is fastened to the bosses 50 with bolts 70 screwed into the bosses 50.

On the rear surface of the housing base 11, the air duct 30 is disposed. At one end of the air duct 30 (that is, at one end of each air duct wall 12), a fan 31 is disposed to generate cooling air. On the rear surface of the housing base 11 (that is, on the other surface thereof), a region 112 (which is a region where the heat sink is disposed) is disposed having a surface planed by a known appropriate technique. The region 112 is at a position corresponding to the power module 22. The heat sink 60 is mounted on the region 112.

The heat sink 60 includes a base portion 61 and a plurality of fins 62. The heat sink 60 is a caulked heat sink in which the base portion 61 and the plurality of fins 62 are caulked to one another with a known appropriate caulking process. The heat sink 60 cools the power module 22, which is among the electronic components disposed in the main portion 20. The base portion 61 is made of a material different from the material of the housing base 11. In this embodiment, the base portion 61 is made of an aluminum alloy (examples including, but not limited to, A6063, which is an Al—Mg—Si alloy) having approximately twice the thermal conductivity of the aluminum alloy of the housing base 11 (examples including, but not limited to, ADC12 alloy, which is an Al—Si—Cu alloy). The material of the base portion 61 is not limited to aluminum alloys. It is also possible to use any other materials having high thermal conductivity. Each of the fins 62 is made of, for example, an aluminum plate and is caulked to the rear surface of the base portion 61 (as seen on the front-left side in FIGS. 2 and 3, and on the lower side in FIG. 4). The length of each fin 62 is assumed D2. The heat sink 60 is fastened to the rear surface of the housing base 11 with bolts 80 screwed into the base portion 61.

Thus, the power module 22 is mounted to the front surface of the housing base 11, while the base portion 61 of the heat sink 60 is mounted to the rear surface of the housing base 11. This results in the housing base 11 disposed between the power module 22 and the base portion 61 of the heat sink 60. This ensures that heat generated at the power module 22 is first transferred to the housing base 11, through which the heat is then transferred to the heat sink 60 and the air duct walls 12, through which the heat is finally discharged (see the dashed arrows in FIG. 4).

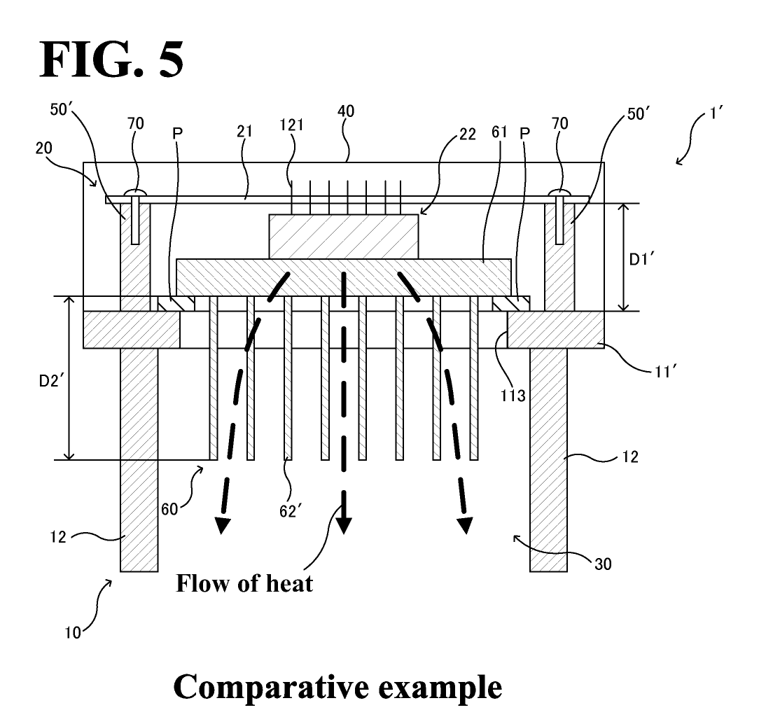

Prior to reciting advantageous effects of the above-described embodiment, a comparative example will be described by referring to FIG. 5. FIG. 5 corresponds to FIG. 4. For ease of comparison, like reference numerals designate corresponding or identical elements throughout FIGS. 4 and 5.

As shown in FIG. 5, an inverter device 1′ according to the comparative example and the inverter device 1 according to the above-described embodiment are similar, but different in that the inverter device 1′ includes a housing base 11′, a plurality of bosses 50′, and fins 62′, as opposed to the housing base 11, the plurality of bosses 50, and the fins 62. Another difference is the positions of the power module 22 and the heat sink 60. Specifically, in the comparative example, the housing base 11′ has an opening 113. The heat sink 60 is mounted to the housing base 11′ in such a manner that the fins 62′ of the heat sink 60 are passed through the opening 113 of the housing base 11′ in the direction from the front side (as seen on the upper side in FIG. 5) to the rear side of (as seen on the lower side in FIG. 5) of the housing base 11′, and thereby the base portion 61 of the heat sink 60 is secured to the front surface of the housing base 11′. In this respect, a gasket P (or a sealing material) is disposed between the base portion 61 of the heat sink 60 and the housing base 11′, and thereby the opening 113 of the housing base 11′ is hermetically sealed. In the comparative example, the power module 22 is in close contact with the front surface of the base portion 61 of the heat sink 60 (as seen on the upper side in FIG. 5). Thus, the base portion 61 of the heat sink 60 is in close contact with the power module 22, and the protrusion defined by the fins 62′ is accommodated in the air duct 30. This makes the heat of the power module 22 discharged. The distance between the housing base 11′ and the substrate 21, that is, the length of each boss 50′, is assumed D1′ (D1′>D1). The length of each fin 62 is assumed D2′ (D2′>D2). The inverter device 1′ is otherwise similar to the inverter device 1 according to the above-described embodiment.

The following are noted regarding the inverter device 1′ according to the comparative example. The comparative example structurely requires hermetic sealing of the opening 113 of the housing base 11′ by disposing the gasket P (or a sealing material) between the base portion 61 of the heat sink 60 and the housing base 11′. The intervention of the gasket P (or a sealing material) prevents or reduces the transfer, if any, of the heat of the power module 22 to the housing base 11′ through the base portion 61 of the heat sink 60. This makes the heat discharged from the heat sink 60 alone (see the dashed arrows in FIG. 5), resulting in insufficient cooling efficiency. Additionally, the comparative example structurely possesses a possibility of degraded sealing performance of the opening 113 of the housing base 11′ through wear of the gasket P (or a sealing material). This can cause a leakage of air from the air duct 30 into the main portion 20. Additionally, the comparative example structurely requires a space immediately under the substrate 21 to dispose the power module 22 and the base portion 61 of the heat sink 60. This enlarges the distance between the housing base 11′ and the substrate 21 (that is, the length of each boss 50′), resulting in an enlarged main portion 20. Additionally, since the space immediately under the substrate 21 accommodates the base portion 61 of the heat sink 60, which is larger in area than the power module 22, the positioning of the bosses 50′ to support the substrate 21 becomes restrictive.

Contrarily, in the inverter device 1 according to the embodiment, the power module 22 is disposed on the front surface of the housing base 11, while the heat sink 60 is disposed on the rear surface of the housing base 11 at a position corresponding to the power module 22. This results in the housing base 11 disposed between the power module 22 and the base portion 61 of the heat sink 60. This ensures that heat generated at the power module 22 is first transferred to the housing base 11, through which the heat is then transferred to the heat sink 60, through which the heat is finally discharged. That is, not only the heat sink 60 but also the housing 10, including the housing base 11, serves as a cooler, resulting in improved cooling efficiency. Accordingly, the heat of the power module 22 is sufficiently cooled. The improvement in cooling efficiency ensures a reduction in size of the heat sink 60 (that is, a reduction in length of the fins 62), if it is assumed that the heat sink 60 and the comparative example have the same cooling efficiency. That is, if the cooling efficiency is the same in this embodiment and the comparative example, a D2<D2′ relationship is ensured.

The following are additional advantageous effects of this embodiment over the comparative example or like configurations that require the gasket P (or a sealing material). In this embodiment, there is no need for providing an opening on the housing base 11 for the heat sink 60 to pass through. The housing base 11 serves as a partition between the main portion 20 and the air duct 30, and eliminates or minimizes a leakage of air from the air duct 30 into the main portion 20. Since no gasket P (or sealing material) is used, the piece-part count decreases. Additionally, in this embodiment, the heat sink 60 is disposed on the rear surface of the housing base 11. This ensures a uniform length of the protrusion defined by the fins 62 of the heat sink 60 in the air duct 30, thereby stabilizing the cooling efficiency. The elimination of the opening on the housing base 11 is also preferred in terms of moldability in the case where the housing 10 of the inverter device 1 is integrally die-cast.

Additionally, in this embodiment, the base portion 61 of the heat sink 60 is disposed on the rear surface of the housing base 11. This eliminates the need for a space immediately under the substrate 21 to dispose the base portion 61, and shortens the distance between the housing base 11 and the substrate 21 (that is, the length D1 of each boss 50). This in turn reduces the size of the main portion 20, and consequently, reduces the size of the inverter device 1. Additionally, in this embodiment, the base portion 61 of the heat sink 60 is not disposed immediately under the substrate 21. This provides a greater freedom of choice on where to dispose the bosses 50.

Additionally, the heat sink 60 according to this embodiment is a caulked heat sink, in which the base portion 61 and the plurality of fins 62 are caulked to one another by caulking. This diminishes the gaps between the narrow-spaced fins 62 and ensures a greater number of fins 62 to be disposed on the base portion 61. This results in improved heat discharge performance of the heat sink 60.

The following are additional advantageous effects of this embodiment. Regarding the arrangement of the heat sink 60 on the rear surface of the housing base 11, two possible configurations are contemplated. One configuration is that the housing base 11 and the heat sink 60 are integrally die-cast, and the other configuration is that the housing base 11 and the heat sink 60 are mutually separate entities. In the case of the integral molding, the heat sink 60 is made of the same material as the material of the housing base 11. Contrarily, when a caulked heat sink is used as in this embodiment, it is necessary that the housing base 11 and the heat sink 60 be mutually separate entities. This is because if the housing base 11 and the base portion 61 of the heat sink 60 integrally molded by die casting or other methods, the base portion 61 is necessarily made of the same material as the material of the housing base 11. This can inhibit the improvement of heat discharge performance because of restrictions associated with the properties of the material and with the molding of the fins. That is, since this embodiment uses a caulked heat sink, the housing base 11 and the heat sink 60 are mutually separate entities. This ensures use of a material for the heat sink 60 that is different from and higher in thermal conductivity than the material of the housing base 11. This, as a result, improves the heat discharge performance of the heat sink 60. According to a comparison of material properties, the caulked heat sink, where the base portion 61 is made of an A6063 alloy, has approximately twice the thermal conductivity of the heat sink that is integrally die-cast with the housing base from an ADC12 alloy.

Additionally, in the embodiment, the housing base 11 and the base portion 61 of the heat sink 60 are made of different materials. This ensures use of a material for the heat sink 60 that is different from and higher in thermal conductivity than the material of the housing base 11. This, as a result, improves the heat discharge performance of the heat sink 60.

The following are additional advantageous effects of this embodiment. The housing base 11 is made of an aluminum alloy subjected to die casting, which involves heat expansion and heat contraction. This causes fine protrusions and depressions on the surface of the housing base 11. In this embodiment, the protrusions and depressions are removed by planing the region 112 on the rear surface of the housing base 11 and the region 111 on the front surface of the housing base 11. This improves the heat conductivity between the housing base 11 and the heat sink 60, and the heat conductivity between the power module 22 and the housing base 11. This, as a result, improves the cooling efficiency.

A modification will be described below.

### (1) Integral Die-Casting of the Housing Base, the Air Duct Walls, and the Bosses

While in the above embodiment the housing base 11, the two air duct walls 12, and the plurality of bosses 50 are separate entities, this should not be construed in a limiting sense. The housing base, the two air duct wall, and the plurality of the boss may be integrally die-cast.

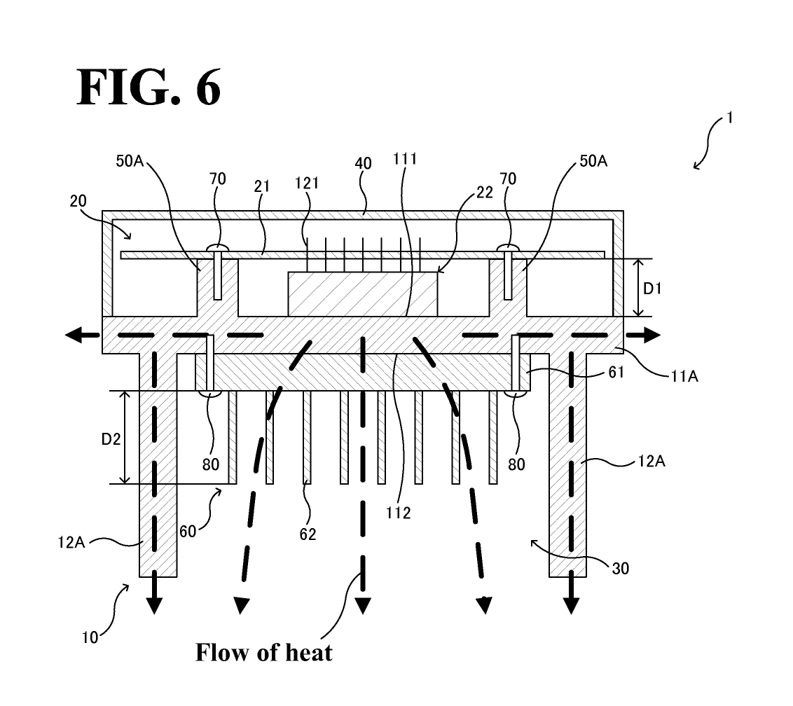

As shown in FIG. 6, an inverter device 1 according to this modification and the inverter device 1 according to the above-described embodiment are similar, but different in that the inverter device 1 according to this modification includes a housing base 11A, two air duct walls 12A, and a plurality of bosses 50A, as opposed to the housing base 11, the two air duct walls 12, and the plurality of bosses 50. The inverter device 1 according to this modification is otherwise similar to the inverter device 1 according to the above-described embodiment. Specifically, in this modification, the housing base 11A, the two air duct walls 12A, and the plurality of bosses 50A are integrally die-cast from an aluminum alloy (examples including, but not limited to, ADC12, which is an Al—Si—Cu alloy). This reduces the piece-part count and the steps count for assembly, compared with making the components separately.

Obviously, numerous modifications and variations of the present invention are possible in light of the above teachings. It is therefore to be understood that within the scope of the appended claims, the invention may be practiced otherwise than as specifically described herein.

What is claimed as new and desired to be secured by Letters Patent of the United States is:

1. A motor control apparatus configured to control driving of a motor, the motor control apparatus comprising:
a housing base having one surface and another surface;
a main portion on the one surface of the housing base, the main portion comprising a substrate;
an air duct through which cooling air passes, the air duct being on the other surface of the housing base;
a heat dissipating component on the one surface of the housing base, the heat dissipating component being coupled to the substrate; and
a heat sink comprising a base portion and at least one fin, the heat sink being on the other surface of the housing base at a position corresponding to the heat dissipating component with the housing base disposed between the base portion and the heat dissipating component.

2. The motor control apparatus according to claim 1, wherein the heat sink comprises a caulked heat sink in which the base portion and the at least one fin are caulked to one another.

3. The motor control apparatus according to claim 1, wherein the housing base and the base portion of the heat sink comprise mutually different materials.

4. The motor control apparatus according to claim 1, wherein a region on the other surface of the housing base where the heat sink is disposed has a planed surface.

5. The motor control apparatus according to claim 1, wherein a region on the one surface of the housing base where the heat dissipating component is disposed has a planed surface.

6. The motor control apparatus according to claim 1, further comprising:
at least one boss upright on the one surface of the housing base to support the substrate; and
at least one air duct wall upright on the other surface of the housing base to constitute a side wall of the air duct,
wherein the housing base, the at least one boss, and the at least one air duct wall together comprise an integrally die-cast structure.

7. The motor control apparatus according to claim 1, wherein the heat dissipating component comprises a power module comprising a semiconductor device.

8. The motor control apparatus according to claim 2, wherein the housing base and the base portion of the heat sink comprise mutually different materials.

9. The motor control apparatus according to claim 2, wherein a region on the other surface of the housing base where the heat sink is disposed has a planed surface.

10. The motor control apparatus according to claim 3, wherein a region on the other surface of the housing base where the heat sink is disposed has a planed surface.

11. The motor control apparatus according to claim 5, wherein a region on the one surface of the housing base where the heat dissipating component is disposed has a planed surface.

12. The motor control apparatus according to claim 3, wherein a region on the one surface of the housing base where the heat dissipating component is disposed has a planed surface.

13. The motor control apparatus according to claim 4, wherein a region on the one surface of the housing base where the heat dissipating component is disposed has a planed surface.

14. The motor control apparatus according to claim 8, wherein a region on the one surface of the housing base where the heat dissipating component is disposed has a planed surface.

15. The motor control apparatus according to claim 9, wherein a region on the one surface of the housing base where the heat dissipating component is disposed has a planed surface.

16. The motor control apparatus according to claim 10, wherein a region on the one surface of the housing base where the heat dissipating component is disposed has a planed surface.

17. The motor control apparatus according to claim 2, further comprising:
at least one boss upright on the one surface of the housing base to support the substrate; and
at least one air duct wall upright on the other surface of the housing base to constitute a side wall of the air duct,
wherein the housing base, the at least one boss, and the at least one air duct wall together comprise an integrally die-cast structure.

18. The motor control apparatus according to claim 3, further comprising:
at least one boss upright on the one surface of the housing base to support the substrate; and
at least one air duct wall upright on the other surface of the housing base to constitute a side wall of the air duct,
wherein the housing base, the at least one boss, and the at least one air duct wall together comprise an integrally die-cast structure.

19. The motor control apparatus according to claim 4, further comprising:
at least one boss upright on the one surface of the housing base to support the substrate; and
at least one air duct wall upright on the other surface of the housing base to constitute a side wall of the air duct,
wherein the housing base, the at least one boss, and the at least one air duct wall together comprise an integrally die-cast structure.

20. The motor control apparatus according to claim 5, further comprising:
at least one boss upright on the one surface of the housing base to support the substrate; and
at least one air duct wall upright on the other surface of the housing base to constitute a side wall of the air duct,
wherein the housing base, the at least one boss, and the at least one air duct wall together comprise an integrally die-cast structure.
